(19) United States
(12) Patent Application Publication
(10) Pub. No.: US 2005/0142880 A1
(43) Pub. Date: Jun. 30, 2005

(54) Polymer removal method for use in manufacturing semiconductor devices

(76) Inventor: Tae Won Park, Seoul (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/023,065

(22) Filed: Dec. 27, 2004

(30) Foreign Application Priority Data
Dec. 27, 2003 (KR) 10-2003-0098372

(51) Int. Cl. H01L 21/302; H01L 21/461

(52) U.S. Cl. 438/689

(57) ABSTRACT

Polymer removal methods for use in manufacturing semiconductor devices are disclosed. An example polymer removal method places wafers on which metal patterns are formed on a wet station employing a batch spin method. The example method treats the wafers with a chemical while rotating the wafers at a first speed that varies and discharges the chemical and rinses the wafers while rotating the wafers at a second speed greater than the first speed.

### TECHNICAL FIELD

The present disclosure relates to semiconductor devices, and more particularly, to a polymer removal method for use in manufacturing semiconductor devices.

### BACKGROUND

Generally, in manufacturing semiconductor devices, metal wires or traces are made of aluminum or copper. After dry etch for forming such metal wires, polymers might remain as reaction byproducts on side walls or upper surfaces of the metal wires. Polymers are typically removed using chemical solvents such as fluorine (F)-based C30T01 or C30T02.

A wet station employing a dip method or a batch spin method of processing 25 to 50 sheets of wafers in a batch may be used for removing or washing out polymers. However, in this case, polymers remain in metal layers and devices having a high density of metal patterns, thereby causing severe defects. Conventionally, to remove polymers from such metal wires or patterns, a chemical (e.g., a solvent) process is performed once at a constant speed or revolutions per minute (RPM) and then a rinse treatment at a higher speed is performed once.

With this conventional process, the polymers are often not melted completely and some of the polymers may remain. Typically, in the conventional process, the chemical treatment is performed while rotating wafers at a low speed, and then the solvent in which the polymers are melted is removed while rotating the wafers at a high speed. At this time, because the chemical treatment and the rinse treatment are performed only one time, the removal of polymers is limited. In addition, because the chemical treatment is performed only once at a constant speed, the polymers are not melted completely and, thus, the polymers are not removed completely. Remaining or residual polymers may cause defects such as, for example, void defects of tungsten.

### BRIEF DESCRIPTION OF THE DRAWINGS

FIG. 1 is a graph schematically illustrating an example polymer removal method.

FIG. 2 is a graph schematically illustrating another example polymer removal method.

### DETAILED DESCRIPTION

In general, the example methods described herein may be used to effectively remove polymers, which are byproducts generated in metal patterns after forming the metal patterns.

One example polymer removal method places wafers on which metal patterns are formed on a wet station employing a batch spin method; treats the wafers with a chemical while rotating the wafers at a first rotational speed, which is varied in a stepwise manner or step-by-step; and discharges the chemical and rinses the wafers while rotating the wafers at a second rotational speed greater than the first rotational speed.

Another example polymer removal method places wafers on which metal patterns are formed on a wet station employing a batch spin method; sequentially repeats a treatment procedure at least two times, the treatment procedure including treating the wafers with a chemical while rotating the wafers at a first speed and rinsing the wafers treated with the chemical; and discharges the chemical and rinses the wafers while rotating the wafers at a second speed greater than the first speed.

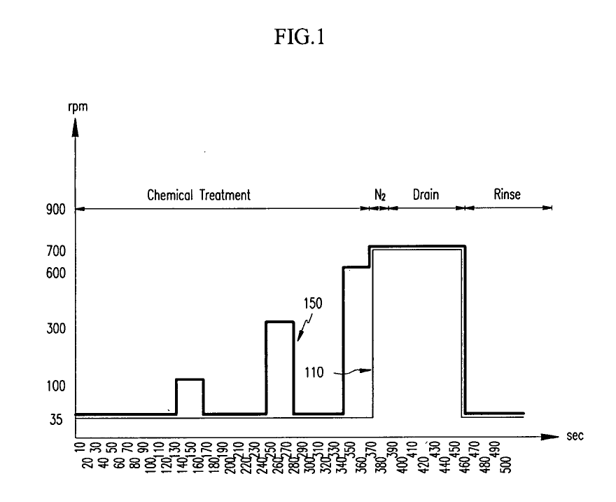

In some known polymer removal methods (indicated by a reference numeral 110 of FIG. 1), wafers on which metal patterns are formed are placed on a wet station employing a batch spin method and are subjected to a chemical treatment at a low speed, for example, at about 35 RPM. Thereafter, the chemical in which polymers are melted is removed and discharged from the wafers while supplying nitrogen gas (N2) and rotating the wafers at a high speed, for example, at about 750 RPM. In this way, the polymers are removed from the wafers.

FIG. 1 is a graph schematically illustrating an example polymer removal method. With the polymer removal method of FIG. 1, the wafers on which the metal patterns are formed are placed on the wet station employing a batch spin method and are then subjected to a chemical treatment in which the rotational speed of the wafers is varied (e.g., in a stepwise manner or step-by-step) at the time of the chemical treatment. That is, by varying the rotational speed from about 35 RPM to 700 RPM, a polymer removing effect of the chemical is enhanced.

For example, the chemical treatment is first performed at about 35 RPM and then the rotational speed is increased to 100 RPM. Thereafter, the speed is decreased to 35 RPM again, is increased again to 300 RPM, is decreased again to 35 RPM, and then is increased again to 600 RPM. In this way, by varying and increasing the rotational speed in this manner, the polymer removal effect can be enhanced and the reaction in which the polymers are melted in the chemical is promoted. At this time, the intermediate low-speed rotation period is introduced to allow the wafers to be wet with the chemical.

Thereafter, by rotating the wafers at a high speed, for example, at about 750 RPM while supplying nitrogen gas (N2), the chemical in which the polymers are melted is removed and discharged (indicated by a reference numeral 150 of FIG. 1).

In this way, the polymers can be effectively removed from the metal patterns on the wafers. Therefore, it is possible to decrease the defect rate (e.g., tungsten void defects) due to the polymers and increase the yield. It is also possible to accomplish a decrease in defects at the time of estimating reliability of a device.

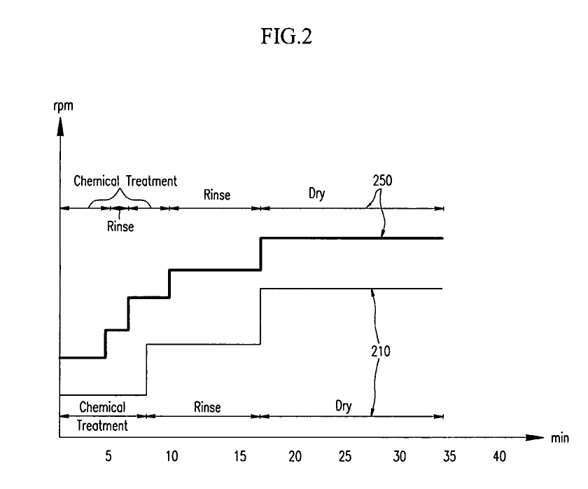

FIG. 2 is a graph schematically illustrating another example polymer removal method. Conventionally, wafers on which metal patterns are formed are placed on a wet station employing a batch spin method and then are subjected to a chemical treatment at a low speed, for example, at about 35 RPM. Thereafter, the chemical in which polymers are melted is removed and discharged from the wafers while supplying nitrogen gas N2 and rotating the wafers at a high speed, for example, at about 750 RPM, and then the wafers are dried at a higher speed. In this way, the polymers are removed from the wafers (indicated by a reference numeral 210 of FIG. 2).

However, using the second example polymer removal method of FIG. 2, the wafers on which the metal patterns are formed are placed on the wet station employing a batch spin method and are then subjected to multiple chemical treatment procedures within which a chemical treatment and a rinse treatment are sequentially repeated. At this time, it is preferable that the rotational speed of the wafers is gradually increased while sequentially performing a chemical treatment, a rinse treatment, a chemical treatment, a rinse treatment, etc. For example, by varying the rotational speed of the wafers in a stepwise manner from about 35 RPM to 700 RPM and repeating the chemical treatment and the rinse treatment as a unit or procedure, the polymer removing effect of the chemical can be enhanced.

Thereafter, by rotating the wafers at a higher rotational speed, the chemical in which the polymers are melted is discharged from the wafers, thereby drying the wafers (indicated by a reference numeral 250 of FIG. 2).

In the second example method of FIG. 2, a chemical treatment and a rinse treatment function as a chemical treatment procedure, and by treatment procedure at least two times, the chemical treatment effect after the rinse treatment with pure water DI, the polymer melting effect at a small rotational speed, and the polymer detaching effect at a large rotational speed can be all used satisfactorily, thereby removing the polymers.

In this way, the polymers can be effectively removed from the metal patterns on the wafers. Therefore, it is possible to accomplish decrease in defect rate due to the polymers and increase in yield, specifically, decrease in tungsten void defect. It is also possible to accomplish decrease in defect at the time of estimating reliability of a device.

While the examples herein have been described in detail with reference to example embodiments, it is to be understood that the coverage of this patent is not limited to the disclosed embodiments, but, on the contrary, is intended to cover various modifications and equivalent arrangements included within the sprit and scope of the appended claims.

1. A polymer removal method comprising:
placing wafers on which metal patterns are formed on a wet station employing a batch spin method;
treating the wafers with a chemical while rotating the wafers at a first speed that varies; and
discharging the chemical and rinsing the wafers while rotating the wafers at a second speed greater than the first speed.

2. The polymer removal method of claim 1, wherein in the treating the wafers with the chemical, the first speed increases with time.

3. The polymer removal method of claim 2, wherein the first speed varies between 35 RPM and 700 RPM.

4. The polymer removal method of claim 2, further comprising decreasing the first speed to a third speed smaller than the first speed.

5. The polymer removal method of claim 4, wherein the third speed is about 35 RPM.

6. A polymer removal method comprising:
placing wafers on which metal patterns are formed on a wet station employing a batch spin method;
sequentially repeating a treatment procedure at least two times, the treatment procedure including treating the wafers with a chemical while rotating the wafers at a first speed and rinsing the wafers treated with the chemical; and
discharging the chemical and rinsing the wafers while rotating the wafers at a second speed greater than the first speed.

7. The polymer removal method of claim 6, wherein the first speed is increased as the treatment procedure is repeated.

8. The polymer removal method of claim 6, wherein rinsing in the treatment procedure is performed at a third speed larger than the first speed.
